(19) United States
(12) Patent Application Publication
(10) Pub. No.: US 2007/0018274 A1
(43) Pub. Date: Jan. 25, 2007

(54) Semiconductor circuit arrangement and method

(76) Inventors: Dietrich Bonart, Bad Abbach (DE); Walter Hartner, Bad Abbach-Peissing (DE); Hermann Gruber, Regensburg (DE); Andreas Meiser, Unterhaching (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/478,912

(22) Filed: Jun. 30, 2006

(30) Foreign Application Priority Data
Jun. 30, 2005 (DE) 10 2005 030 638.1

(51) Int. Cl. H01L 29/00

(52) U.S. Cl. 257/506

(57) ABSTRACT

One aspect of the present invention relates to a semiconductor circuit arrangement and to a method for producing the latter. One aspect of the invention is that, as a result of a connecting trench structure and an isolation trench structure of a semiconductor circuit being in direct spatial proximity with respect to one another, an additional capacitor device is formed. The capacitance of said capacitor device is connected as a usable capacitance for the semiconductor circuit and is connected to the latter.

### CROSS-REFERENCE TO RELATED APPLICATIONS

This Utility Patent Application claims priority to German Patent Application No. DE 10 2005 030 638.1, filed on Jun. 30, 2005, which is incorporated herein by reference.

### BACKGROUND

One aspect of the present invention relates to a semiconductor circuit arrangement and to a method for producing the latter. In particular, one aspect relates, to a trench structure or trench capacitance, which is formed from isolation and connecting trenches in the field of so-called smart power technologies.

In addition to the miniaturization and large-scale integration of the semiconductor circuits on which the semiconductor circuit arrangements are based, simplification of the corresponding production processes is also an important aspect when developing modern semiconductor technologies, in particular in order to be able to eradicate sources of error during production and to lower production costs.

In certain semiconductor circuit arrangements, additional usable capacitances are also needed, inter alia, to implement certain functions. In this case, it is known practice, in principle, to realize these additional usable capacitances using corresponding additional capacitor devices, a certain process engineering outlay also being given to these additional capacitors as groups of additional elements.

The disadvantage of the known procedure is thus that each additional capacitor component with the corresponding useful capacitance to be used also entails higher complexity of the actual operation for producing the semiconductor circuit arrangement. On the other hand, certain other basic structures which are present, for example, in the form of so-called connecting trenches or isolation trenches and are provided at particular positions in the circuit layout of the semiconductor circuit arrangement and the underlying semiconductor circuit are formed in order to achieve other basic functions and in order to ensure functional reliability.

### SUMMARY

One aspect of the invention provides a semiconductor circuit arrangement and a corresponding method for producing a semiconductor circuit arrangement, in which an additional capacitor function with a corresponding capacitance can be implemented in a simple but reliable manner with a small additional outlay on process engineering.

In one embodiment of an inventive semiconductor circuit arrangement, a semiconductor circuit, a connecting trench structure for the semiconductor circuit and an isolation trench structure for the semiconductor circuit are formed. In one case, the connecting trench structure is formed in direct spatial proximity with respect to the isolation trench structure in such a manner that an additional capacitor device is formed thereby, the capacitance of said capacitor device being connected as a usable capacitance for the semiconductor circuit and being connected to the latter.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a schematic and sectional side view which illustrates a first exemplary embodiment of an inventive semiconductor circuit arrangement.

FIG. 2 illustrates a schematic and partially sectional plan view of another embodiment of the inventive semiconductor circuit arrangement.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

An aspect of the present invention is to implement a capacitor device (which is to be additionally provided) by a connecting trench structure (which is to be formed anyway) and a corresponding isolation trench structure being formed in direct spatial proximity with respect to one another. The result is that the additional capacitance that is realized thereby is connected as a usable capacitance for the semiconductor circuit, is connected to the latter, and can be used by the latter.

A first aspect of the invention thus provides a semiconductor circuit arrangement, in which a semiconductor circuit is formed, in which a connecting trench structure for the semiconductor circuit is formed, in which an isolation trench structure for the semiconductor circuit is formed, and in which the connecting trench structure and the isolation trench structure are formed in spatial proximity with respect to one another in such a manner that an additional capacitor device for the semiconductor circuit is formed thereby. The capacitance of said capacitor device is connected as a usable capacitance for the semiconductor circuit and is connected to the latter.

One embodiment of the inventive semiconductor circuit arrangement provides for the connecting trench structure and the isolation trench structure to be formed at a comparatively small lateral distance from one another.

Another embodiment of the inventive semiconductor circuit arrangement alternatively or additionally provides for the connecting trench structure and the isolation trench structure to be formed in a semiconductor material region or in an epitaxial region on a semiconductor material region, in one case, with a mesa region in between.

One embodiment of the inventive semiconductor circuit arrangement alternatively or additionally provides for the connecting trench structure for the semiconductor circuit to be formed with a first electrically conductive material region, which is electrically contact-connected to the walls and to the bottom of the connecting trench structure, as a first electrode device of the additional capacitor device.

Another embodiment of the inventive semiconductor circuit arrangement alternatively or additionally provides for the isolation trench structure for the semiconductor circuit to be formed with a second electrically conductive material region, which is electrically insulated from the walls and from the bottom of the isolation trench structure, as a second electrode device of the additional capacitor device.

One embodiment of the inventive semiconductor circuit arrangement alternatively or additionally provides for the additional capacitor device and its capacitance to be formed in such a manner that they are laterally delimited by an additional delimiting isolation trench structure and are closed.

Furthermore, another embodiment of the inventive semiconductor circuit arrangement may alternatively or additionally provide for the additional delimiting isolation trench structure for the semiconductor circuit to be formed with a third electrically conductive material region which is electrically insulated from the walls and from the bottom of the additional delimiting isolation trench structure.

In addition, in another development of the inventive semiconductor circuit arrangement, it is alternatively or additionally conceivable for the isolation trench structure to be formed such that it laterally surrounds the connecting trench structure, in one case in a concentric manner.

Another embodiment of the inventive semiconductor circuit arrangement may also alternatively or additionally provide for the additional delimiting isolation trench structure to be formed such that it laterally surrounds the connecting trench structure and the isolation trench structure, in one case in a concentric manner.

Another embodiment of the inventive semiconductor circuit arrangement alternatively or additionally provides for the connecting trench structure, the isolation trench structure and/or, in one case, the additional delimiting isolation trench structure to be filled and formed, as a respective first, second and third electrically conductive material region, with a filling comprising a material or a combination of materials from the group comprising polysilicon, metals and tungsten.

The semiconductor circuit may be in the form of a power semiconductor circuit and, in one example, in the form of a smart power circuit.

Another aspect of the invention provides a method for producing a semiconductor circuit arrangement, in which a semiconductor circuit is formed, in which a connecting trench structure for the semiconductor circuit is formed, in which an isolation trench structure for the semiconductor circuit is formed, and in which the connecting trench structure and the isolation trench structure are formed in spatial proximity with respect to one another in such a manner that an additional capacitor device for the semiconductor circuit is formed thereby. The capacitance of said capacitor device is connected as a usable capacitance for the semiconductor circuit and is connected to the latter.

One embodiment of the inventive method for producing the inventive semiconductor circuit arrangement provides for the connecting trench structure and the isolation trench structure to be formed at a comparatively small lateral distance from one another.

Another embodiment of the inventive method for producing the inventive semiconductor circuit arrangement alternatively or additionally provides for the connecting trench structure and the isolation trench structure to be formed in a semiconductor material region or in an epitaxial region on a semiconductor material region, in one example, with a mesa region in between.

One embodiment of the inventive method for producing the inventive semiconductor circuit arrangement alternatively or additionally provides for the connecting trench structure for the semiconductor circuit to be formed with a first electrically conductive material region, which is electrically contact-connected to the walls and to the bottom of the connecting trench structure, as a first electrode device of the additional capacitor device.

Another embodiment of the inventive method for producing the inventive semiconductor circuit arrangement alternatively or additionally provides for the isolation trench structure for the semiconductor circuit to be formed with a second electrically conductive material region, which is electrically insulated from the walls and from the bottom of the isolation trench structure, as a second electrode device of the additional capacitor device.

One embodiment of the inventive method for producing the inventive semiconductor circuit arrangement alternatively or additionally provides for the additional capacitor device and its capacitance to be formed in such a manner that they are laterally delimited by an additional delimiting isolation trench structure and are closed.

Furthermore, another embodiment of the inventive method for producing the inventive semiconductor circuit arrangement may alternatively or additionally provide for the additional delimiting isolation trench structure for the semiconductor circuit to be formed with a third electrically conductive material region which is electrically insulated from the walls and from the bottom of the additional delimiting isolation trench structure.

In addition, in another embodiment of the inventive method for producing the inventive semiconductor circuit arrangement, it is alternatively or additionally conceivable for the isolation trench structure to be formed such that it laterally surrounds the connecting trench structure, in one example, in a concentric manner.

Another embodiment of the inventive method for producing the inventive semiconductor circuit arrangement may also alternatively or additionally provide for the additional delimiting isolation trench structure to be formed such that it laterally surrounds the connecting trench structure and the isolation trench structure, in one example, in a concentric manner.

Another embodiment of the inventive method for producing the inventive semiconductor circuit arrangement alternatively or additionally provides for the connecting trench structure, the isolation trench structure and/or, in one example, the additional delimiting isolation trench structure to be filled and formed, as a respective first, second and third electrically conductive material region, with a filling comprising a material or a combination of materials from the group comprising polysilicon, metals and tungsten.

The semiconductor circuit may be in the form of a power semiconductor circuit and, in one example, in the form of a smart power circuit.

These and other aspects of the present invention are explained in more detail below:

In one example, the invention also relates, inter alia, to a trench capacitance including isolation and connecting trenches, in one example, for power semiconductor arrangements and/or for smart power technologies.

In smart power technologies, for example, capacitances are used as common components. Additional working steps are generally needed to produce these capacitances, and this is associated with higher production costs.

In one embodiment of the invention, isolation trenches and connecting trenches, which are provided as standard structures and are used for a buried layer, to produce a capacitance using a suitable design.

Previous concepts for providing a trench capacitance include additional working steps, for example, the formation of wells which are diffused in to a great depth. Other concepts are based on poly-poly capacitances or metal-insulation-metal capacitances. These solutions, however, increase the production costs.

In one embodiment of the invention, an isolation trench, for example, is also placed, inter alia, at a small distance from an out-diffused connecting trench. In this context, the phrase “small distance” means that the out-diffusion of the connecting trench reaches as far as the isolation trench. This produces a capacitance between the isolation trench, which has been filled with poly, and the connecting trench without the need for wells which have been diffused in to a great depth. The electrodes of the capacitances are, on the one hand, the poly filling of the isolation trench and, on the other hand, the out-diffused connecting trench.

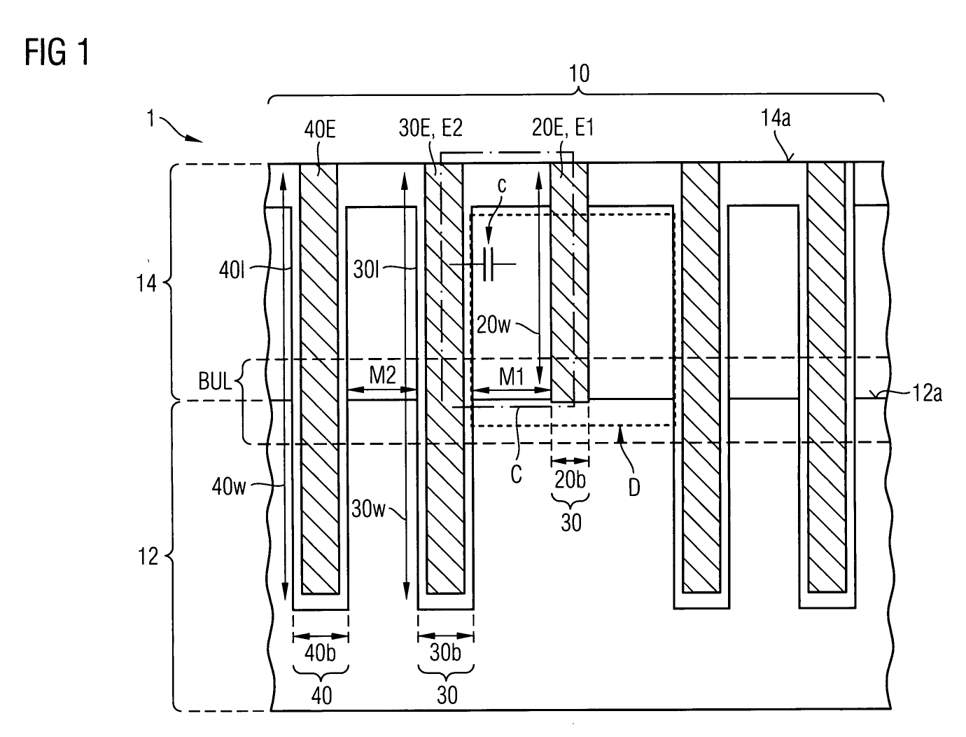

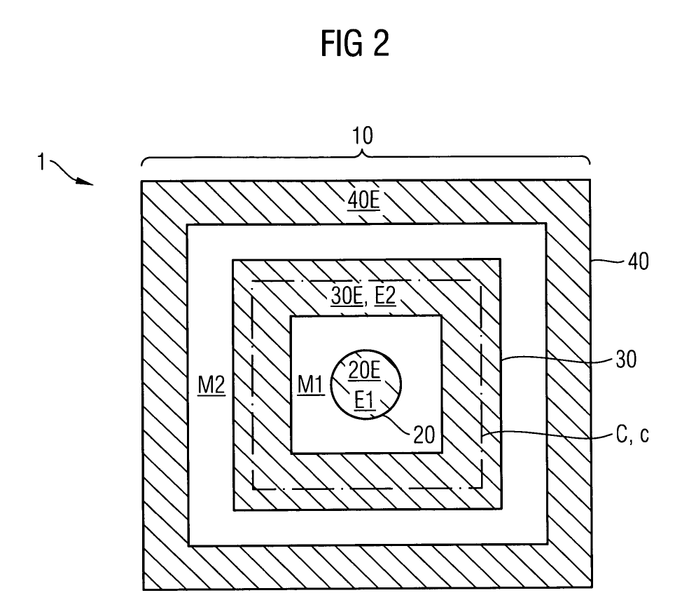

A layout example of one embodiment of an inventive trench capacitance is described in FIGS. 1 and 2. In the exemplary embodiment, the capacitance is delimited toward the outside by an isolation trench ring.

FIG. 1 is a schematic and sectional side view of a first embodiment of semiconductor circuit arrangement 1.

The semiconductor circuit arrangement 1 is based on a semiconductor material region 12 having a surface region 12a on which is formed an epitaxial region 14 which has a surface 14a and has the semiconductor circuit 10 which forms the basis of the semiconductor circuit arrangement 1 and is not specified in any more detail in the embodiment 1. The semiconductor circuit 10 may be, in one example, a power semiconductor circuit.

A so-called buried layer BUL is provided such that it is at a distance from the surface region 12a of the semiconductor material region or semiconductor substrate 12 and is below the surface 14a of the epitaxial region 14. Starting from the surface region 14a of the epitaxial region 14, a number of trench structures 20, 30 and 40 are formed such that they are essentially vertically driven into the interior of the epitaxial region 14.

In this case, a so-called connecting trench structure 20 which has a wall region 20w or a plurality of walls 20w and a bottom 20b and which is formed with a first electrically conductive material region 20E that is in direct electrical contact with the walls 20w and 20b of the connecting trench structure 20 is laterally centrally present. An isolation trench structure 30 which extends downward from the surface region 14a of the epitaxial region 14 to beneath the buried layer BUL of the epitaxial region 14 is provided such that it is laterally spaced apart by means of a first mesa region M1. The isolation trench structure 30 which has walls 30w and a bottom 30b is filled with a second electrically conductive material region 30E which is electrically insulated from the walls 30w and from the bottom 30b by means of an insulation layer 301.

The first electrically conductive material region 20E of the connecting trench structure 20 and the second electrically conductive material region 30E of the isolation trench structure 30 form a respective first and a second electrode or electrode device E1 and E2. These electrode devices are used to define, assisted by the insulation layer 301 for insulating the second electrically conductive material region 30E from the walls 30w and the bottom 30b of the isolation trench structure 30, an additional capacitor device C having a capacitance c, which can be additionally used and is connected or can be connected to the semiconductor circuit 10 in order to be used by the latter.

An additional and delimiting isolation trench structure 40, which has wall regions 40w and a bottom region 40b and is filled with a third electrically conductive material region 40E such that it is electrically insulated, via an insulation layer 40I, from the wall regions 40w and the bottom region 40b of the additional and delimiting isolation trench structure 40, is provided such that it is spatially laterally spaced apart from the isolation trench structure 30 by means of a second mesa region M2.

FIG. 2 is a schematic and partially sectional plan view of another embodiment of semiconductor circuit arrangement 1.

In this case too, the semiconductor circuit arrangement 1 is based on a semiconductor material region 12, if appropriate with a corresponding epitaxial layer 14. In the section of the semiconductor circuit arrangement 1 illustrated, a connecting trench structure 20 having the corresponding first conductive material region 20E as a first electrode device E1 for the additional capacitor device C is illustrated in the center. An isolation trench structure 30 having a corresponding filling of a second electrically conductive material region 30E as a second electrode E2 for the additional capacitor device C for the semiconductor circuit 10 is provided at a certain distance which is laterally defined by a first mesa region M1. In this case, the isolation trench structure 30 surrounds the connecting trench structure 20 in a concentric manner.

An additional and delimiting isolation trench structure 40 having a corresponding filling in the form of a third conductive material region 40E is then respectively provided, likewise concentrically with respect to the previously mentioned structures, such that it is somewhat spatially laterally spaced apart by means of a second mesa region M2.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor circuit arrangement comprising:
a semiconductor circuit;
a connecting trench structure for the semiconductor circuit; and
an isolation trench structure for the semiconductor circuit;
wherein the connecting trench structure and the isolation trench structure are formed in spatial proximity with respect to one another such that an additional capacitor device for the semiconductor circuit is formed thereby; and
wherein the capacitance of said capacitor device is connected as a usable capacitance for the semiconductor circuit and is connected thereto.

2. The semiconductor circuit arrangement of claim 1, wherein the connecting trench structure and the isolation trench structure are formed at a comparatively small lateral distance from one another.

3. The semiconductor circuit arrangement of claim 1, wherein the connecting trench structure and the isolation trench structure are formed in a semiconductor material region or in an epitaxial region on a semiconductor material region with a mesa region in between.

4. The semiconductor circuit arrangement of claim 1, wherein the connecting trench structure for the semiconductor circuit is formed with a first electrically conductive material region, which is electrically contact-connected to the walls and to the bottom of the connecting trench structure, as a first electrode device of the additional capacitor device.

5. The semiconductor circuit arrangement of claim 1, wherein the isolation trench structure for the semiconductor circuit is formed with a second electrically conductive material region, which is electrically insulated from the walls and from the bottom of the isolation trench structure, as a second electrode device of the additional capacitor device.

6. The semiconductor circuit arrangement of claim 1, wherein the additional capacitor device and its capacitance are formed in such a manner that they are laterally delimited by an additional delimiting isolation trench structure (40) and are closed.

7. The semiconductor circuit arrangement of claim 6, wherein the additional delimiting isolation trench structure for the semiconductor circuit is formed with a third electrically conductive material region which is electrically insulated from the walls and from the bottom of the additional delimiting isolation trench structure.

8. The semiconductor circuit arrangement of claim 1, wherein the isolation trench structure is formed such that it laterally surrounds the connecting trench structure in a concentric manner.

9. The semiconductor circuit arrangement of claim 6, wherein the additional delimiting isolation trench structure is formed such that it laterally surrounds the connecting trench structure and the isolation trench structure in a concentric manner.

10. The semiconductor circuit arrangement of claim 6, wherein the connecting trench structure, the isolation trench structure and/or the additional delimiting isolation trench structure is/are filled and formed, as a respective first, second and third electrically conductive material region, with a filling of a material or a combination of materials from the group comprising polysilicon, metals and tungsten.

11. The semiconductor circuit arrangement of claim 1, wherein the semiconductor circuit is in the form of a power semiconductor circuit and in the form of a smart power circuit.

12. A method for producing a semiconductor circuit arrangement comprising:
forming a semiconductor circuit;
forming a connecting trench structure for the semiconductor circuit;
forming an isolation trench structure for the semiconductor circuit;
forming the connecting trench structure and the isolation trench structure in spatial proximity with respect to one another in such a manner that an additional capacitor device for the semiconductor circuit is formed thereby; and
connecting the capacitance of said capacitor device to the semiconductor circuit as a usable capacitance for the semiconductor circuit.

13. The method of claim 12, further comprising forming the connecting trench structure and the isolation trench structure at a comparatively small lateral distance from one another.

14. The method of claim 12, further comprising forming the connecting trench structure and the isolation trench structure in a semiconductor material region or in an epitaxial region on a semiconductor material region with a mesa region (M1) in between.

15. The method of claim 12, further comprising forming the connecting trench structure for the semiconductor circuit with a first electrically conductive material region, which is electrically contact-connected to the walls and to the bottom of the connecting trench structure, as a first electrode device of the additional capacitor device.

16. The method of claim 12, further comprising forming the isolation trench structure for the semiconductor circuit with a second electrically conductive material region, which is electrically insulated from the walls and from the bottom of the isolation trench structure, as a second electrode device of the additional capacitor device.

17. The method of claim 12, further comprising forming the additional capacitor device and its capacitance in such a manner that they are laterally delimited by an additional delimiting isolation trench structure and are closed.

18. The method of claim 17, further comprising forming the additional delimiting isolation trench structure for the semiconductor circuit with a third conductive material region which is electrically insulated from the walls and from the bottom of the additional delimiting isolation trench structure.

19. The method of claim 12, further comprising forming the isolation trench structure such that it laterally surrounds the connecting trench structure in a concentric manner.

20. The method of claim 17, further comprising forming the additional delimiting isolation trench structure such that it laterally surrounds the connecting trench structure and the isolation trench structure in a concentric manner.

21. The method of claim 17, further comprising filling and forming the connecting trench structure, the isolation trench structure and/or, the additional delimiting isolation trench structure as a respective first, second and third electrically conductive material region with a filling comprising a material or a combination of materials from the group comprising polysilicon, metals and tungsten.

22. The method of claim 12, further comprising forming the semiconductor circuit as a power semiconductor circuit and as a smart power circuit.

23. A semiconductor circuit arrangement comprising:
a semiconductor circuit;
a connecting trench structure for the semiconductor circuit;
an isolation trench structure for the semiconductor circuit; and
means forming an additional capacitor device coupled to the semiconductor circuit such that capacitance of the capacitor device is used by the semiconductor device.
